(19) United States
(12) Patent Application Publication
(10) Pub. No.: US 2025/0089314 A1
(43) Pub. Date: Mar. 13, 2025

(54) THREE DIMENSIONAL SEMICONDUCTOR DEVICE AND METHOD OF MANUFACTURING THE SAME

(71) Applicant: Samsung Electronics Co., Ltd., Suwon-si (KR)

(72) Inventors: Donghoon HWANG, Suwon-si (KR); Hyojin KIM, Suwon-si (KR); Byungho MOON, Suwon-si (KR); Myungil KANG, Suwon-si (KR); Doyoung CHOI, Suwon-si (KR)

(73) Assignee: Samsung Electronics Co., Ltd., Suwon-si (KR)

(21) Appl. No.: 18/588,089

(22) Filed: Feb. 27, 2024

(30) Foreign Application Priority Data
Sep. 13, 2023 (KR) 10-2023-0121528

(51) Int. Cl. H01L 29/06; H01L 27/092; H01L 29/417; H01L 29/423; H01L 29/775; H01L 29/786

(52) U.S. Cl. CPC H10D 62/121; H10D 30/43; H10D 30/6729; H10D 30/6735; H10D 30/6757; H10D 84/85

(57) ABSTRACT

A three-dimensional semiconductor device includes a first active region on a substrate, including a first active region on a substrate, including a lower channel pattern and lower source/drain patterns connected to the lower channel pattern, the lower channel pattern including a plurality of lower semiconductor patterns stacked and spaced apart from each other in a first direction that is perpendicular to an upper surface of the substrate, and the lower semiconductor patterns including a lowermost first semiconductor pattern, a second active region stacked on the first active region, including an upper channel pattern and an upper source/drain pattern connected to the upper channel pattern, a lower gate electrode on the lower channel pattern, and a lower insulating pattern under the first semiconductor pattern, the first semiconductor pattern spaced apart from the lower insulating pattern in the first direction. The lower gate electrode includes a first portion adjacent to a first sidewall of the lower insulating pattern and extending in the first direction from an upper surface to a bottom surface of the lower gate electrode, a second portion adjacent to a second sidewall of the lower insulating pattern and extending in the first direction from the upper surface to the bottom surface of the lower gate electrode, the second sidewall facing the first sidewall in a second direction which is perpendicular to the first direction, and a third portion in contact with a bottom surface of the lower insulating pattern and extending from the first portion to the second portion in the second direction.

### CROSS-REFERENCE TO RELATED APPLICATIONS

This U.S. non-provisional patent application claims priority under 35 U.S.C. § 119 to Korean Patent Application No.10-2023-0121528, filed on Sep. 13, 2023, in the Korean Intellectual Property Office, the entire contents of which are hereby incorporated by reference.

### BACKGROUND

The inventive concepts relate to a three-dimensional semiconductor device and a method of manufacturing the same, and more particularly, relates to a three-dimensional semiconductor device including a field effect transistor and a method of manufacturing the same.

A semiconductor device includes an integrated circuit including metal oxide semiconductor field effect transistors (MOSFETs). As sizes and design rules of the semiconductor device are gradually decreased, sizes of the MOSFETs are also increasingly scaled down. The scale down of MOSFETs may deteriorate operating characteristics of the semiconductor device. Accordingly, various research has been conducted to develop methods of fabricating semiconductor devices having superior performance while overcoming issues associated with high integration of the semiconductor devices.

### SUMMARY

Some example embodiments of the inventive concepts provide three-dimensional semiconductor devices with improved integration and electrical characteristics.

The problem to be solved by the inventive concept is not limited to the problems mentioned above, and other problems not mentioned will be clearly understood by those skilled in the art from the description below.

A three-dimensional semiconductor device according to some example embodiments of the inventive concepts may include a first active region on a substrate, including a lower channel pattern and lower source/drain patterns connected to the lower channel pattern, the lower channel pattern including a plurality of lower semiconductor patterns stacked and spaced apart from each other in a first direction that is perpendicular to an upper surface of the substrate, and the lower semiconductor patterns including a first semiconductor pattern, a second active region stacked on the first active region, including an upper channel pattern and an upper source/drain pattern connected to the upper channel pattern, a lower gate electrode on the lower channel pattern, and a lower insulating pattern under the first semiconductor pattern, the first semiconductor pattern spaced apart from the lower insulating pattern in the first direction. The lower gate electrode includes a first portion adjacent to a first sidewall of the lower insulating pattern and extending in the first direction from an upper surface to a bottom surface of the lower gate electrode, a second portion adjacent to a second sidewall of the lower insulating pattern and extending in the first direction from the upper surface to the bottom surface of the lower gate electrode, the second sidewall facing the first sidewall in a second direction which is perpendicular to the first direction, and a third portion in contact with a bottom surface of the lower insulating pattern and extending from the first portion to the second portion in the second direction.

A three-dimensional semiconductor device according to some example embodiments of the inventive concept may include a first active region on a substrate, including a lower channel pattern and lower source/drain patterns connected to the lower channel pattern, the lower channel pattern including a plurality of lower semiconductor patterns stacked and spaced apart from each other in a first direction, and the lower semiconductor patterns including a first semiconductor pattern, a second active region stacked on the first active region, including an upper channel pattern and an upper source/drain pattern connected to the upper channel pattern, a lower gate electrode on the lower channel pattern, and a lower insulating pattern under the first semiconductor pattern. The first semiconductor pattern is spaced apart from the lower insulating pattern in the first direction. The lower gate electrode surrounds upper surface, both sidewalls, and bottom surface of the lower insulating pattern.

A three-dimensional semiconductor device according to some example embodiments of the inventive concepts may include a first active region on a substrate, including a lower channel pattern and lower source/drain patterns connected to the lower channel pattern, the lower channel pattern including a plurality of lower semiconductor patterns stacked and spaced apart from each other in a first direction, and the lower semiconductor patterns including a first semiconductor pattern, a second active region stacked on the first active region, including an upper channel pattern and an upper source/drain pattern connected to the upper channel pattern, a lower gate electrode on the lower channel pattern, a lower gate contact electrically connected to the lower gate electrode, and a lower insulating pattern under the first semiconductor pattern. The first semiconductor pattern is spaced apart from the lower insulating pattern in the first direction. A level of a bottom surface of the lower gate electrode is lower than a level of a bottom surface of the lower insulating pattern. A maximum width of the lower gate electrode is greater than a maximum width of the lower insulating pattern.

### BRIEF DESCRIPTION OF THE DRAWINGS

Various example embodiments will be more clearly understood from the following brief description taken in conjunction with the accompanying drawings. The accompanying drawings represent non-limiting, example embodiments as described herein.

FIG. 1 is a conceptual diagram for illustrating a logic cell of a semiconductor device according to comparative examples of the inventive concepts.

FIG. 2 is a conceptual diagram for illustrating a logic cell of a semiconductor device according to various example embodiments of the inventive concepts.

FIG. 3 is a plan view for illustrating a three-dimensional semiconductor device according to various example embodiments of the inventive concept.

FIGS. 4A to 4C are cross-sectional views taken along lines A-A′, B-B′, and C-C′ of FIG. 3, respectively.

FIG. 5 is an enlarged view of region ‘M’ in FIG. 4B.

FIGS. 6A to 17B are cross-sectional views for illustrating a method of manufacturing a semiconductor device according to various example embodiments of the inventive concepts.

### DETAILED DESCRIPTION

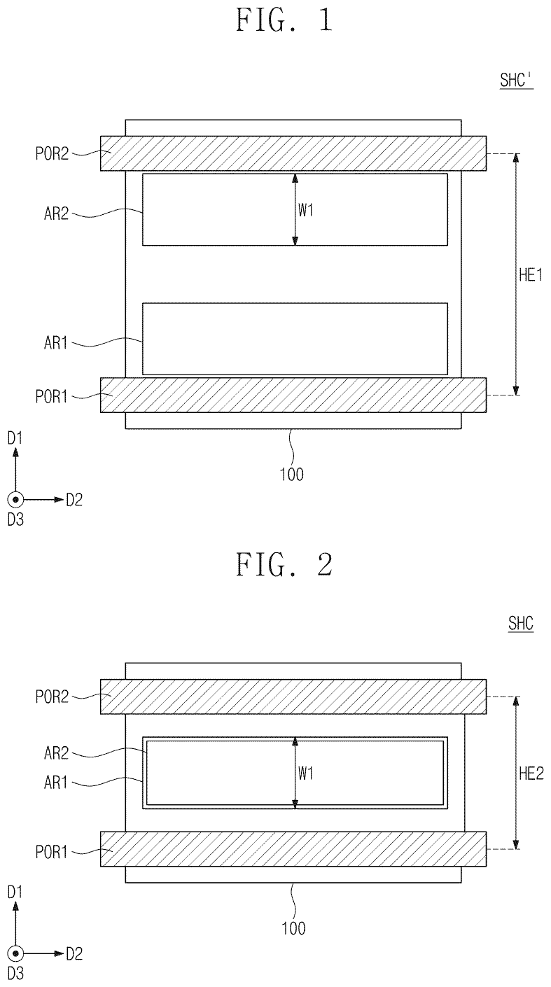

FIG. 1 is a conceptual diagram for illustrating a logic cell of a semiconductor device according to comparative example embodiments of the inventive concepts. FIG. 1 illustrates a logic cell of a two-dimensional device according to a comparative example embodiments of the inventive concepts.

Referring to FIG. 1, a single height cell SHC′ may be provided. In detail, a first power line POR1 and a second power line POR2 may be provided on a substrate 100. A drain voltage VDD, that is, a power voltage, may be applied to either the first power line POR1 or the second power line POR2. A source voltage VSS, that is, a ground voltage, may be applied to the other one of the first power line POR1 and the second power line POR2. For example, the source voltage VSS may be applied to the first power line POR1, and the drain voltage VDD may be applied to the second power line POR2.

The single height cell SHC′ may be defined between the first power line POR1 and the second power line POR2. The single height cell SHC′ may include a lower active region LAR and an upper active region UAR. One of the lower active region LAR and the upper active region UAR may be a PMOSFET region, and the other one of the lower active region LAR and the upper active region UAR may be an NMOSFET region. For example, the lower active region LAR may be an NMOSFET region, and the upper active region UAR may be a PMOSFET region. That is, the single height cell SHC′ may have a CMOS structure provided between the first power line POR1 and the second power line POR2.

The three-dimensional semiconductor device according to comparative example embodiments is a two-dimensional device, and transistors in a front end of line (FEOL) layer may be arranged two-dimensionally. For example, an NMOSFET of the lower active region LAR a the PMOSFET of the upper active region UAR may be arranged to be spaced apart from each other in a first direction D1.

Each of the lower active region LAR and the upper active region UAR may have a first width W1 in the first direction D1. A length of the single height cell SHC′ according to comparative example embodiments in the first direction DI may be defined as a first height HE1. The first height HE1 may be substantially equal to a distance (e.g., pitch) between the first power line POR1 and the second power line POR2.

The single height cell SHC′ may constitute one logic cell. In the present specification, a logic cell may refer to a logic element (e.g., AND, OR, XOR, XNOR, inverter, etc.) that performs a specific function. That is, the logic cell may include transistors for configuring a logic element and wirings connecting the transistors to each other.

As the single height cell SHC′ according to the present comparative example includes a two-dimensional element, the lower active region LAR and upper active region UAR do not overlap each other and are arranged to be spaced apart from each other in the first direction D1. Accordingly, the first height HE1 of the single height cell SHC′ should be defined to encompass both the lower and upper active regions LAR and UAR spaced apart from each other in the first direction D1. As a result, the first height HE1 of the single height cell SHC′ according to the present comparative example may be relatively large. That is, the area of the single height cell SHC′ according to the present comparative example may be relatively large.

FIG. 2 is a conceptual diagram for illustrating a logic cell of a semiconductor device according to various example embodiments of the inventive concepts. FIG. 2 illustrates a logic cell of a three-dimensional device according to various example embodiments of the inventive concepts.

Referring to FIG. 2, a single height cell SHC including a three-dimensional device (e.g., a stacked transistor) may be provided. In detail, a first power line POR1 and a second power line POR2 may be provided on a substrate 100. The single height cell SHC may be defined between the first power line POR1 and the second power line POR2.

The single height cell SHC may include a lower active region LAR and an upper active region UAR. One of the lower active region LAR and the upper active region UAR may be a PMOSFET region, and the other one of the lower active region LAR and the upper active region UAR may be an NMOSFET region.

The three-dimensional semiconductor device according to various example embodiments may be a three-dimensional device, and transistors of a FEOL layer may be vertically stacked. The lower active region LAR may be provided as a bottom tier on the substrate 100, and the upper active region UAR may be stacked on the lower active region LAR as a top tier. For example, an NMOSFET in the lower active region LAR may be provided on the substrate 100, and a PMOSFET in the upper active region UAR may be stacked on the NMOSFET. The lower active region LAR and the upper active region UAR may be spaced apart from each other in the vertical direction, that is, in a third direction D3.

Each of the lower active region LAR and the upper active region UAR may have a first width W1 in the first direction D1. A length of the single height cell SHC according to various example embodiments in the first direction D1 may be defined as a second height HE2.

As the single height cell SHC according to various example embodiments includes a three-dimensional element, that is, stacked transistors, the lower active region LAR and upper active region UAR may overlap each other. Accordingly, the second height HE2 of the single height cell SHC may have a size that encompasses the first width W1 described above. As a result, the second height HE2 of the single height cell SHC according to various example embodiments may be smaller than the first height HE1 of the single height cell SHC′ of FIG. 1 described above. That is, the area of the single height cell SHC according to various example embodiments may be relatively small. The three-dimensional semiconductor device according to various example embodiments may improve a high density of the device by reducing the area of a logic cell.

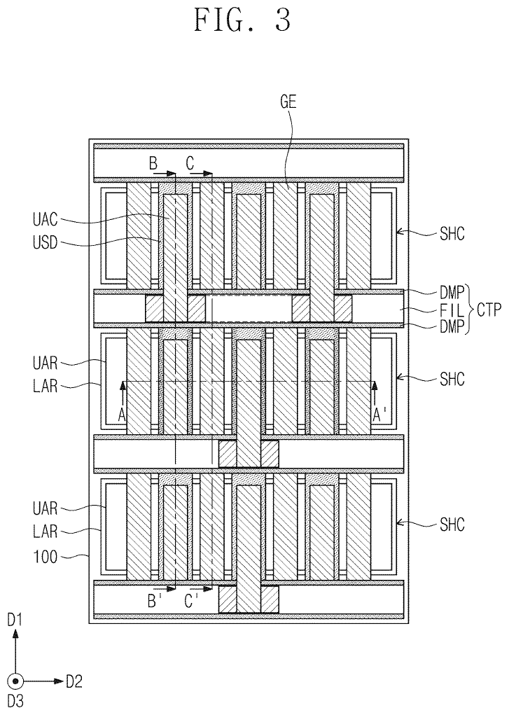

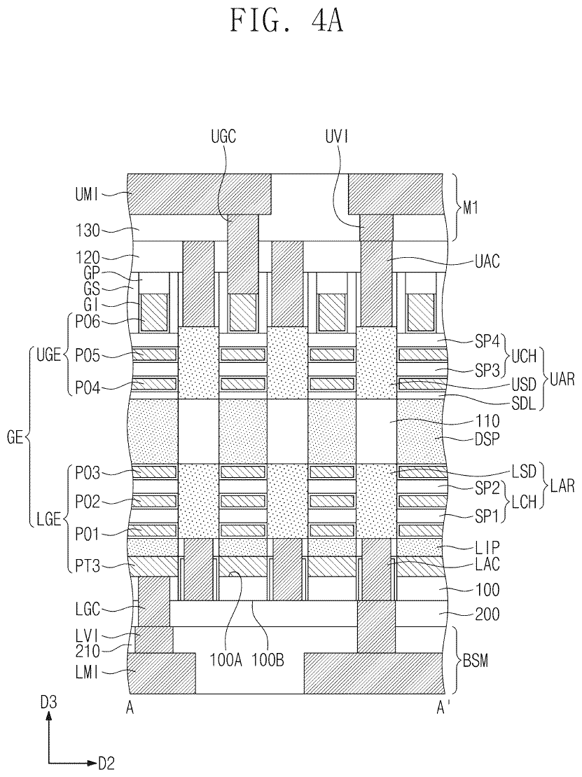

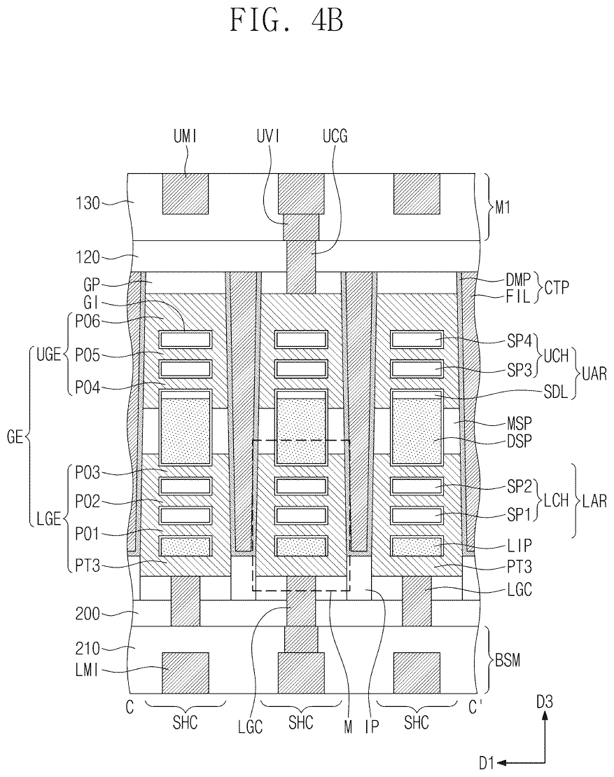

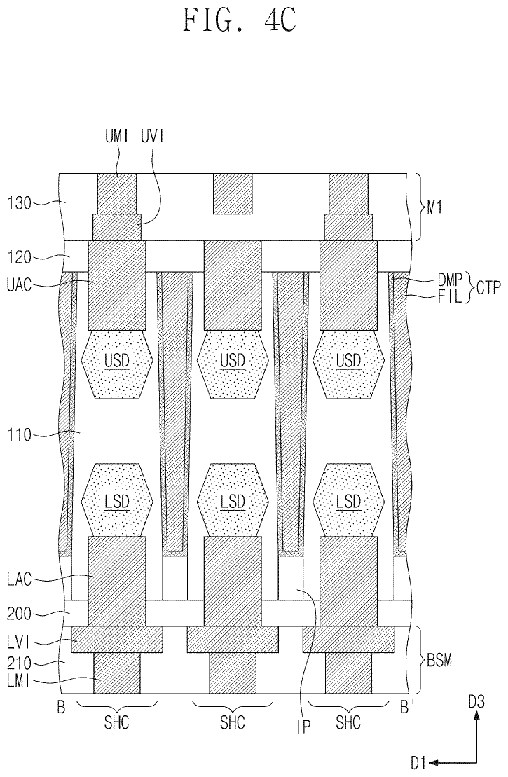

FIG. 3 is a plan view for illustrating a three-dimensional semiconductor device according to various example embodiments of the inventive concepts. FIGS. 4A to 4C are cross-sectional views taken along lines A-A′, B-B′, and C-C′ of FIG. 3, respectively. A three-dimensional semiconductor device shown in FIGS. 3 and 4A to 4C is an example that represents the single height cell of FIG. 2 in detail.

Referring to FIGS. 3 and 4A to 4C, single height cells SHC may be provided on a substrate 100. The substrate 100 may include a first surface 100A and a second surface 100B that face each other. The first surface 100A may be a front side of the substrate 100, and the second surface 100B may be a backside of the substrate 100. In some example embodiments of the inventive concepts, the substrate 100 may be an insulating substrate including a silicon-based insulating material (e.g., silicon oxide and/or silicon nitride). In other example embodiments of the inventive concepts, the substrate 100 may be a semiconductor substrate containing silicon, germanium, silicon germanium, etc.

In various example embodiments of the inventive concepts, each single height cell SHC may be a logic cell constituting a logic circuit. Each single height cell SHC may be a logic cell including the three-dimensional element described above with reference to FIG. 2. The single height cells SHC may be arranged in a first direction D1.

Each of the single height cells SHC may include a lower active region LAR and an upper active region UAR sequentially stacked on the substrate 100. One of the lower and upper active regions LAR and UAR may be a PMOSFET region, and the other of the lower and upper active regions LAR and UAR may be an NMOSFET region. The lower active region LAR may be provided in a bottom tier of the FEOL layer, and the upper active region UAR may be provided in a top tier of the FEOL layer. The NMOSFET and PMOSFET of the lower and upper active regions LAR and UAR may be vertically stacked to form a three-dimensional stacked transistor. In some example embodiments, the lower active region LAR may be an NMOSFET region, and the upper active region UAR may be a PMOSFET region.

Each of the lower and upper active regions LAR and UAR may have a bar shape or a line shape extending in a second direction D2. A cutting pattern CTP may be provided between adjacent single height cells SHC. The cutting pattern CTP may separate adjacent single height cells SHC from each other. Adjacent single height cells SHC may be spaced apart in the first direction DI by the cutting pattern CTP. The cutting pattern CTP may have a bar shape or a line shape extending in the second direction D2.

The lower active region LAR including lower channel patterns LCH and lower source/drain patterns LSD may be provided on the single height cell SHC. The lower channel pattern LCH may be interposed between a pair of lower source/drain patterns LSD. The lower channel pattern LCH may connect a pair of lower source/drain patterns LSD to each other.

The lower channel pattern LCH may include a first semiconductor pattern SP1 and a second semiconductor pattern SP2 that are stacked and spaced apart from each other. Each of the first and second semiconductor patterns SP1 and SP2 may include silicon (Si), germanium (Ge), or silicon germanium (SiGe). However, example embodiments are not limited thereto. Preferably, each of the first and second semiconductor patterns SP1 and SP2 may include crystalline silicon. Each of the first and second semiconductor patterns SP1 and SP2 may be a nanosheet. As an example, the lower channel pattern LCH may further include one or more semiconductor patterns that are stacked and spaced apart from the first semiconductor pattern SP1. The first semiconductor pattern SP1 may be the lowest semiconductor pattern.

The lower source/drain patterns LSD may be provided on the substrate 100. Each of the lower source/drain patterns LSD may be an epitaxial pattern formed through a selective epitaxial growth (SEG) process. For example, an upper surface of the lower source/drain pattern LSD may be higher than an upper surface of the second semiconductor pattern SP2 of the lower channel pattern LCH.

The lower source drain patterns LSD may be doped with impurities to have a first conductivity type. The first conductivity type may be N-type or P-type. In various example embodiments, the first conductivity type may be N-type. The lower source drain patterns LSD may include silicon (Si) and/or silicon germanium (SiGe). However, example embodiments are not limited thereto.

A first interlayer insulating layer 110 may be provided on the lower source drain pattern LSD. The first interlayer insulating layer 110 may cover the lower source drain patterns LSD.

A lower active contact LAC may be provided below the lower source/drain pattern LSD. The lower active contact LAC may be electrically connected to the lower source/drain pattern LSD. The lower active contact LAC may be buried in the substrate 100. The lower active contact LAC may extend vertically from the second surface 100B to the first surface 100A of the substrate 100. The lower active contact LAC may include a metal selected from the group consisting of copper (Cu), aluminum (Al), ruthenium (Ru), cobalt (Co), tungsten (W), and molybdenum (Mo). However, example embodiments are not limited thereto.

The upper active region UAR may be provided on the first interlayer insulating layer 110. The upper active region UAR may include upper channel patterns UCH and upper source/drain patterns USD. The upper channel patterns UCH may vertically overlap the lower channel patterns LCH, respectively. The upper source/drain patterns USD may vertically overlap the lower source/drain patterns LSD, respectively. The upper channel pattern UCH may be interposed between a pair of upper source/drain patterns USD. The upper channel pattern UCH may connect a pair of upper source/drain patterns USD to each other.

The upper channel pattern UCH may include a third semiconductor pattern SP3 and a fourth semiconductor pattern SP4 that are stacked and spaced apart from each other. The third and fourth semiconductor patterns SP3 and SP4 of the upper channel pattern UCH may include the same semiconductor material as the first and second semiconductor patterns SP1 and SP2 of the lower channel pattern LCH described above. Each of the third and fourth semiconductor patterns SP3 and SP4 may be a nanosheet. As an example, the upper channel pattern UCH may further include one or more semiconductor patterns that are stacked and spaced apart from the third semiconductor pattern SP3.

At least one dummy channel pattern DSP may be interposed between the lower channel pattern LCH and the upper channel pattern UCH. A seed layer SDL may be interposed between the dummy channel pattern DSP and the upper channel pattern UCH.

The dummy channel pattern DSP may be spaced apart from the lower and upper source drain patterns LSD and USD. That is, the dummy channel pattern DSP may not be connected to any source drain pattern. The dummy channel pattern DSP may include a semiconductor material such as silicon (Si), germanium (Ge), or silicon germanium (SiGe), or may include a silicon-based insulating material such as a silicon oxide or silicon nitride layer. However, example embodiments are not limited thereto. In various example embodiments of the inventive concepts, the dummy channel pattern DSP may include the silicon-based insulating material.

The upper source/drain patterns USD may be provided on an upper surface of the first interlayer insulating layer 110. Each of the upper source/drain patterns USD may be an epitaxial pattern formed through a selective epitaxial growth (SEG) process. For example, an upper surface of the upper source/drain pattern USD may be higher than an upper surface of the fourth semiconductor pattern SP4 of the upper channel pattern UCH.

The upper source/drain patterns USD may be doped with impurities to have a second conductivity type. The second conductivity type may be different from the first conductivity type of the lower source/drain pattern LSD. The second conductivity type may be P type. The upper source/drain patterns USD may include silicon germanium (SiGe) and/or silicon (Si). However, example embodiments are not limited thereto.

A plurality of gate electrodes GE may be provided on a single height cell SHC. In detail, the gate electrodes GE may be provided on the stacked lower and upper channel patterns LCH and UCH (refer to FIG. 4B). When viewed from a plan view, the gate electrode GE may have a bar shape extending in the first direction D1. The gate electrode GE may vertically overlap the stacked lower and upper channel patterns LCH and UCH.

The gate electrode GE may be provided on upper surface, bottom surface, and both sidewalls of each of the first to fourth semiconductor patterns SP1 to SP4. That is, the transistor according to some example embodiments may include a three-dimensional field effect transistor (e.g., MBCFET or GAAFET) in which the gate electrode GE three-dimensionally surrounds a channel.

The gate electrodes GE may include a lower gate electrode LGE provided in the bottom tier of the FEOL layer, that is, the lower active region LAR and an upper gate electrode UGE provided in the top tier of the FEOL layer, that is, the upper active region UAR. The lower gate electrode LGE and the upper gate electrode UGE may be vertically spaced apart from each other with a separation pattern MSP therebetween, which will be described later.

The lower gate electrode LGE may extend in a vertical direction (i.e., a third direction D3) from the first surface 100A of the substrate 100 to the separation pattern MSP. The upper active region UGE may extend in the vertical direction D3 from an upper surface of the separation pattern MSP to a gate capping pattern GP. In various example embodiments of the inventive concept, the lower gate electrode LGE and the upper gate electrode UGE may not be connected to each other.

The lower gate electrode LGE may include a first inner electrode PO1 interposed between a lower insulating pattern LIP described later and a first semiconductor pattern SP1, a second inner electrode PO2 interposed between the first semiconductor pattern SP1 and the second semiconductor pattern SP2, and a third inner electrode PO3 interposed between the second semiconductor pattern SP2 and the dummy channel pattern DSP.

The upper gate electrode UGE may include a fourth inner electrode PO4 interposed between the dummy channel pattern DSP (or seed layer SDL) and the third semiconductor pattern SP3, a fifth inner electrode PO5 interposed between the third semiconductor pattern SP3 and the fourth semiconductor pattern SP4, and an outer electrode PO6 on the fourth semiconductor pattern SP4.

A pair of gate spacers GS may be disposed on both sidewalls of the gate electrode GE. Referring to FIG. 4A, the pair of gate spacers GS may be disposed on both sidewalls of the outer electrode PO6. The gate spacers GS may extend in the first direction D1 along the gate electrode GE. The top surfaces of the gate spacers GS may be higher than upper surfaces of the gate electrode GE. The upper surfaces of the gate spacers GS may be coplanar with an upper surface of the gate capping pattern GP, which will be described later. The gate spacers GS may include at least one of SiCN, SiCON, and SiN. In other example embodiments, the gate spacers GS may include a multi-layer formed of at least two of SiCN, SiCON, and SiN. However, example embodiments are not limited thereto.

A gate capping pattern GP may be provided on an upper surface of the gate electrodes GE. The gate capping pattern GP may extend in the first direction D1 along the gate electrode GE. For example, the gate capping pattern GP may include at least one of SiON, SiCN, SiCON, and SiN. However, example embodiments are not limited thereto.

A gate insulating layer GI may be interposed between the gate electrode GE and the first to fourth semiconductor patterns SP1 to SP4. The gate insulating layer GI may include a silicon oxide layer, a silicon oxynitride layer, and/or a high dielectric layer. However, example embodiments are not limited thereto. In various example embodiments of the inventive concepts, the gate insulating layer GI may include a silicon oxide layer directly covering surfaces of the semiconductor patterns SP1 to SP4 and a high dielectric layer on the silicon oxide layer. That is, the gate insulating layer GI may include a multi-layer of a silicon oxide layer and a high dielectric layer.

The high dielectric layer may include a high dielectric constant material that has a higher dielectric constant than that of a silicon oxide layer. As an example, the high dielectric constant material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, and strontium titanium. oxide, lithium oxide, aluminum oxide, lead scandium tantalum oxide, and lead zinc niobate. However, example embodiments are not limited thereto.

The lower gate electrode LGE may include a first work function metal pattern on the first and second semiconductor patterns SP1 and SP2. The upper gate electrode UGE may include a second work function metal pattern on the third and fourth semiconductor patterns SP3 and SP4. Each of the first and second work function metal patterns may include at least one metal selected from the group consisting of titanium (Ti), tantalum (Ta), aluminum (Al), tungsten (W), and molybdenum (Mo) and nitrogen (N). However, example embodiments are not limited thereto. The first and second work function metal patterns may have different work functions. The gate electrode GE may include a low-resistance metal (e.g., at least one of tungsten (W), ruthenium (Ru), aluminum (Al), titanium (Ti), and tantalum (Ta)) on the first and second work function metal patterns. However, example embodiments are not limited thereto. For example, the outer electrode PO6 may further include the low-resistance metal as well as the second work function metal pattern.

A second interlayer insulating layer 120 may be provided on the gate capping pattern GP. An upper surface of the second interlayer insulating layer 120 may be coplanar with upper surfaces of each of upper active contacts UAC, which will be described later.

An upper gate contact UGC may be provided that penetrates the second interlayer insulating layer 120 and the gate capping pattern GP and is electrically connected to the upper gate electrode UGE. The upper active contact UAC and upper gate contact UGC may include a metal selected from the group consisting of copper (Cu), aluminum (Al), ruthenium (Ru), cobalt (Co), tungsten (W), and molybdenum (Mo. However, example embodiments are not limited thereto.

A cutting pattern CTP may be provided between the gate electrodes GE adjacent to each other in the first direction D1. The cutting pattern CTP may separate the adjacent gate electrodes GE from each other. The adjacent gate electrodes GE may be spaced apart in the first direction D1 by the cutting pattern CTP. The cutting pattern CTP may have a bar shape or a line shape extending in the second direction D2.

The cutting pattern CTP may include a liner layer DMP and a buried metal via FIL on the liner layer DMP. The liner layer DMP may be an insulating layer composed of one layer or multiple layers. For example, the buried metal via FIL may be formed of a metal selected from the group consisting of copper (Cu), aluminum (Al), ruthenium (Ru), cobalt (Co), tungsten (W), and molybdenum (Mo). However, example embodiments are not limited thereto.

A third interlayer insulating layer 130 may be provided on the second interlayer insulating layer 120. A first metal layer M1 may be provided in the third interlayer insulating layer 130. The first metal layer M1 may include upper interconnections UMI. The first metal layer M1 may further include an upper via UVI. The upper via UVI may electrically connect the upper interconnection UMI to the upper active contact UAC or upper gate contact UGC. The upper interconnect UMI and the upper via UVI may include a metal selected from the group consisting of copper (Cu), aluminum (Al), ruthenium (Ru), cobalt (Co), tungsten (W), and molybdenum (Mo). However, example embodiments are not limited thereto.

Additional metal layers (e.g., M2, M3, M4, etc.) may be stacked on the first metal layer M1. The first metal layer M1 and the metal layers (e.g., M2, M3, M4, etc.) on the first metal layer M1 may form a back end of line (BEOL) layer of the semiconductor device. The metal layers (e.g., M2, M3, M4, etc.) on the first metal layer M1 may include routing wirings for connecting logic cells to each other.

A first lower interlayer insulating layer 200 may be provided below the second surface 100B of the substrate 100. A second lower interlayer insulating layer 210 may be provided below the first lower interlayer insulating layer 200. A backside metal layer BSM may be provided in the second lower interlayer insulating layer 210. The backside metal layer BSM may include lower interconnections LMI. The backside metal layer BSM may further include a lower via LVI. The lower via LVI may electrically connect either the lower active contact LAC or the lower gate contact LGC to the lower interconnection LMI. The lower interconnect LMI and the lower via LVI may include a metal selected from the group consisting of copper (Cu), aluminum (Al), ruthenium (Ru), cobalt (Co), tungsten (W), and molybdenum (Mo), respectively. However, example embodiments are not limited thereto.

Additional lower metal layers may be stacked below the backside metal layer BSM. In various example embodiments of the inventive concepts, the lower metal layers may include a power transmission network. The power transmission network may include a wiring network for applying a source voltage VSS and a drain voltage VDD to the backside metal layer BSM.

The source voltage VSS and the drain voltage VDD may be applied to the backside metal layer BSM through the power transmission network. Referring to FIG. 4A, one of the source voltage VSS or the drain voltage VDD may be applied to the lower source drain pattern LSD through the lower interconnection LMI, the lower via LVI, and the lower active contact LAC. The other of the source voltage VSS and the drain voltage VDD may be applied from the backside metal layer BSM to the first metal layer M1 through a power tap cell. The voltage applied to the first metal layer M1 through the power tap cell may be applied to the upper source drain pattern USD through the upper interconnection UMI, the upper via UVI, and the upper active contact UAC. The power tap cell may be interposed between adjacent single height cells SHC.

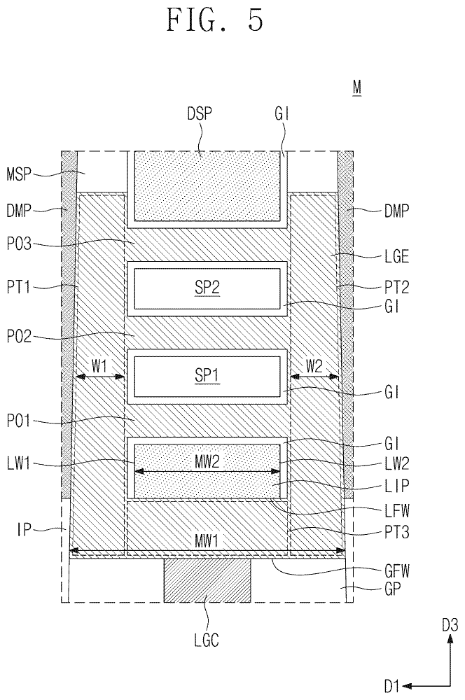

FIG. 5 is an enlarged view of region ‘M’ in FIG. 4B. Thereafter, with reference to FIG. 5, features of the lower gate electrode LGE according to various example embodiments of the inventive concepts will be described in detail.

Referring to FIG. 5, the lower insulating pattern LIP may be provided below the first semiconductor pattern SP1. The first semiconductor pattern SP1 and the lower insulating pattern LIP may be spaced apart in a vertical direction (i.e., in the third direction D3). The first semiconductor pattern SP1 and the lower insulating pattern LIP may be spaced apart from each other with the first inner electrode POI of the lower gate electrode GE. The lower insulating pattern LIP may include a semiconductor material such as silicon (Si), germanium (Ge), or silicon germanium (SiGe), or may include a silicon-based insulating material such as a silicon oxide layer or a silicon nitride layer. However, example embodiments are not limited thereto. The lower insulating pattern LIP may include the same material as the dummy channel pattern DSP.

The lower gate electrode LGE may be provided on the lower channel patterns LCH and the lower insulating pattern LIP. The lower gate electrode LGE may surround each of the first and second semiconductor patterns SP1 and SP2 and the lower insulating pattern LIP. As an example, the lower gate electrode LGE may be provided on upper surface, both sidewalls LW1 and LW2, and bottom surface LFW of the lower insulating pattern LIP. The gate insulating layer GI may be interposed between the upper surface and both sidewalls LW1 and LW2 of the lower insulating pattern LIP, respectively, and the lower gate electrode LGE.

The lower gate electrode LGE may include a first portion PT1 adjacent to the first sidewall LW1 of the lower insulating pattern LIP and extending in the third direction D3, a second portion PT2 adjacent to the second sidewall LW2 of the lower insulating pattern LIP and extending in the third direction D3, and a third portion PT3 in contact with the bottom surface LFW of the lower insulating pattern LIP. The first sidewall LW1 and the second sidewall LW2 may face each other in the first direction D1.

In detail, the first portion PT1 may be a part adjacent to the first sidewall LW1 and extending vertically from the top to the bottom of the lower gate electrode LGE. The second portion PT2 may be adjacent to the second sidewall LW2 and extend vertically from the top to the bottom of the lower gate electrode LGE. Each of the first and second portions PT1 and PT2 may be in contact with a side surface of the liner layer DMP of the adjacent cutting pattern CTP.

The third portion PT3 may be in direct contact with the bottom surface LFW of the lower insulating pattern LIP and may be extended in the first direction D1 from the first portion PT1 to the second portion PT2. As an example, the third portion PT3 may be a portion that extends vertically from the bottom surface LFW of the lower insulating pattern LIP to the bottom surface GFW of the lower gate electrode LGE.

Each of a first width W1 of the first portion PT1 and a second width W2 of the second portion PT2 may increase as approaching the bottom surface GFW of the lower insulating pattern LIP. Widths of the first portion PT1 and the second portion PT2 in the first direction D1 may decrease as moving toward the third direction D3. Each of the first portion PT1 and the second portion PT2 may have a trapezoidal profile.

A width of the lower gate electrode LGE in the first direction D1 may decrease from the bottom surface GFW of the lower gate electrode LGE to the bottom surface LFW of the lower insulating pattern LIP. A first maximum width MW1 of the lower gate electrode LGE in the first direction D1 may be greater than a second maximum width MW2 of the lower insulating pattern LIP in the first direction D1. A width of the bottom surface GFW of the lower gate electrode LGE may be greater than the second maximum width MW2 of the lower insulating pattern LIP. A level of the bottom surface GFW of the lower gate electrode LGE may be lower than a level of the bottom surface LFW of the lower insulating pattern LIP.

Referring again to FIG. 4A, the lower gate contact LGC may be electrically connected to the third portion PT3 of the lower gate electrode LGE. A bottom surface of the lower gate electrode LGE may be positioned at a lower level than the bottom surface of the lower source/drain pattern LCH. Accordingly, the upper surface LAC of the lower active contact LAC may be positioned at a higher level than the upper surface of the lower gate contact LGC.

According to various example embodiments of the inventive concepts, the third portion PT3 of the lower gate electrode LGE may be provided below the lower insulating pattern LIP. By extending the lower gate electrode LGE downward, the lower gate contact LGC connected to the lower gate electrode LGE may have a height difference from the lower active contact LAC. Accordingly, an electrical short between the lower gate contact LGC and the lower active contact LAC may be prevented.

In addition, referring to a method of manufacturing the same described later, a processes for forming the upper gate electrode UGE and the lower gate electrode LGE may be separated, thereby preventing damage to the lower channel patterns LCH. As a result, the three-dimensional semiconductor device according to the inventive concepts may improve reliability and improve integration by reducing cell height.

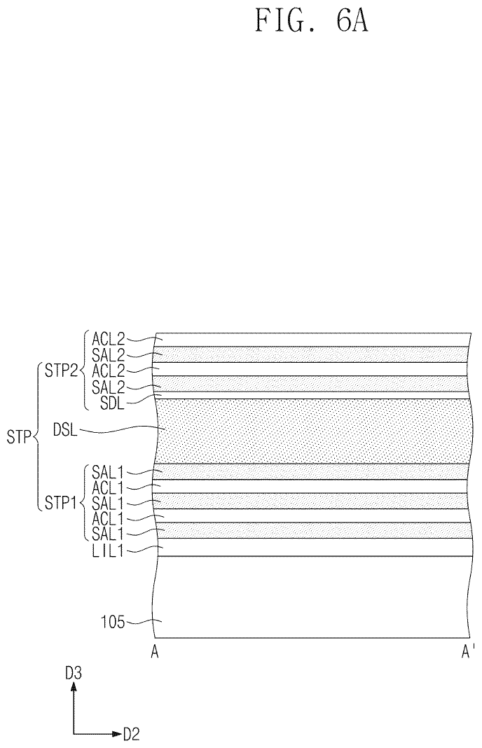

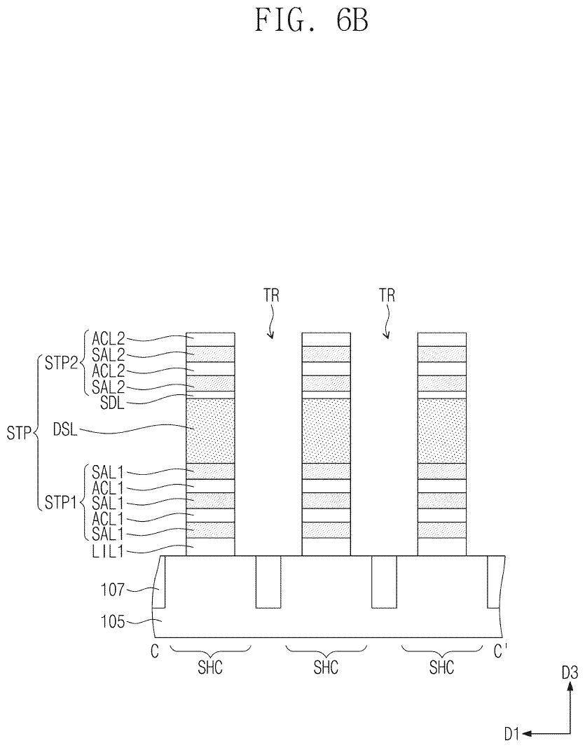

FIGS. 6A to 17B are cross-sectional views for explaining a method of manufacturing a semiconductor device according to various example embodiments of the inventive concepts. In detail, FIGS. 6A, 7A, 8A, 9A, 10, 11A, 12A, 13A, 14A, 15A, 16, and 17A are cross-sectional views corresponding to line A-A′in FIG. 3. FIGS. 6B, 7B, 8B, 9B, 11B, 12B, 13B, 14B, 15B, and 17B are cross-sectional views corresponding to line C-C′ in FIG. 3.

Hereinafter, a method of manufacturing the three-dimensional semiconductor device according to FIGS. 3 to 5 will be described with reference to FIGS. 6A to 17B. To simplify the explanation, descriptions of content that overlaps with the above-mentioned content are omitted.

Referring to FIGS. 6A and 6B, a semiconductor substrate 105 may be provided. The semiconductor substrate 105 may include one of silicon (Si), germanium (Ge), and silicon-germanium (SiGe). For example, the semiconductor substrate 105 may be a single crystal silicon wafer. However, example embodiments are not limited thereto.

A first lower insulating layer LIL1 may be formed on the semiconductor substrate 105. The first lower insulating layer LIL1 may include a silicon-based insulating material (e.g., silicon oxide) and/or a semiconductor material (Si or SiGe). However, example embodiments are not limited thereto.

First sacrificial layers SAL1 and first active layers ACL1 may be alternately stacked on the first lower insulating layer LIL1. The first sacrificial layers SAL1 may include one of silicon (Si), germanium (Ge), and silicon germanium (SiGe), and the first active layers ACL1 may include silicon (Si), germanium (Ge) and silicon germanium (SiGe). For example, the first sacrificial layers SAL1 may include silicon germanium (SiGe), and the first active layers ACL1 may include silicon (Si). A concentration of germanium (Ge) in each of the first sacrificial layers SAL1 may be 10 at % to 30 at %. However, example embodiments are not limited thereto.

A separation layer DSL may be formed on the uppermost first sacrificial layer SAL1. In various example embodiments of the inventive concepts, a thickness of the separation layer DSL may be greater than a thickness of the first sacrificial layer SAL1. The separation layer DSL may include silicon (Si) or silicon germanium (SiGe). However, example embodiments are not limited thereto. When the separation layer DSL includes silicon germanium (SiGe), a concentration of germanium (Ge) in the separation layer DSL may be greater than a concentration of germanium (Ge) in the first sacrificial layer SAL1. For example, the concentration of germanium (Ge) in the separation layer DSL may be 40 at % to 90 at %.

A seed layer SDL may be formed on the separation layer DSL. The seed layer SDL may include the same material as the first active layer ACL1. Second sacrificial layers SAL2 and second active layers ACL2 may be alternately stacked on the seed layer SDL. Each of the second sacrificial layers SAL2 may include the same material as the first sacrificial layer SAL1, and each of the second active layers ACL2 may include the same material as the first active layer ACL1. The separation layer DSL may be interposed between the first sacrificial layer SAL1 and the seed layer SDL.

The stacked first and second sacrificial layers SAL1 and SAL2, first and second active layers ACL1 and ACL2, and separation layer DSL may be patterned to form a stacked pattern STP. Forming the stacked pattern STP may include forming a hard mask pattern on the uppermost second active layer ACL2, and Etching the stacked layers SAL1, SAL2, ACL1, ACL2, SDL and DSL on the semiconductor substrate 105 using the hard mask pattern as an etch mask. While the stacked pattern STP is being formed, an upper portion of the semiconductor substrate 105 may be patterned to form a trench TR defining a single height cell SHC. The stacked pattern STP may have a bar shape or a line shape extending in the second direction D2.

The stacked pattern STP may include a lower stacked pattern STP1 on the first lower insulating layer LIL1, an upper stacked pattern STP2 on the lower stacked pattern STP1, and a separation layer DSL between the lower and upper stacked patterns STP1 and STP2. The lower stacked pattern STP1 may include first sacrificial layers SAL1 and first active layers ACL1 that are alternately stacked. The upper stacked pattern STP2 may include a seed layer SDL and second sacrificial layers SAL2 and second active layers ACL2 alternately stacked on the seed layer SDL.

A device isolation layer 107 may be formed on the semiconductor substrate 105 to fill a lower portion of the trench TR. In detail, an insulating layer covering the stacked patterns STP may be formed on the entire surface of the semiconductor substrate 105. The insulating layer may be recessed until the stacked patterns STP are exposed to form the device isolation layer 107. An upper surface of the device isolation layer 107 may be coplanar with an upper surface of the semiconductor substrate 105.

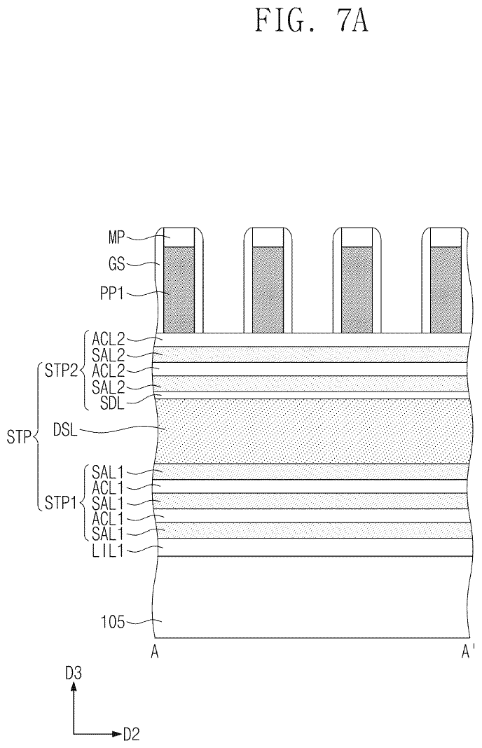

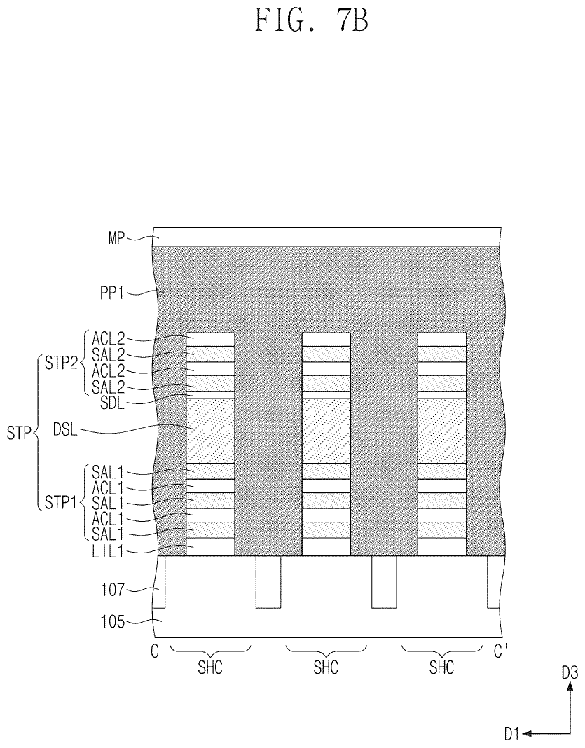

Referring to FIGS. 7A and 7B, a plurality of first sacrificial patterns PPI may be formed across the stacked pattern STP. Each of the first sacrificial patterns PP1 may be formed in a line shape extending in the first direction D1. In detail, forming the first sacrificial pattern PP1 may include forming a sacrificial layer on the entire surface of the semiconductor substrate 105, forming a hard mask pattern MP on the sacrificial layer, and patterning the sacrificial layer using the hard mask pattern MP an etch mask. The sacrificial layer may include amorphous silicon and/or polysilicon. However, example embodiments are not limited thereto.

A pair of gate spacers GS may be formed on both sidewalls of the first sacrificial pattern PP1, respectively. In detail, a spacer layer may be conformally formed on a front surface of the semiconductor substrate 105. The spacer layer may cover the first sacrificial pattern PP1 and the hard mask pattern MP. For example, the spacer layer may include at least one of SiCN, SiCON, and SiN. However, example embodiments are not limited thereto. The spacer layer may be anisotropically etched to form the gate spacers GS.

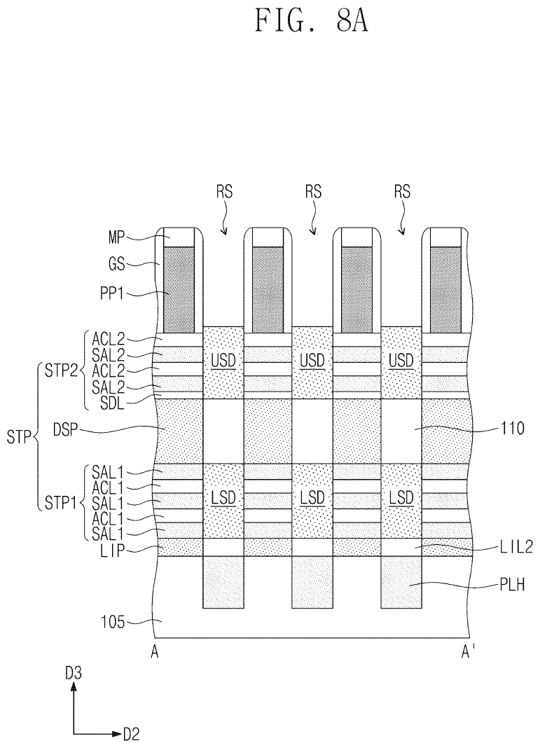

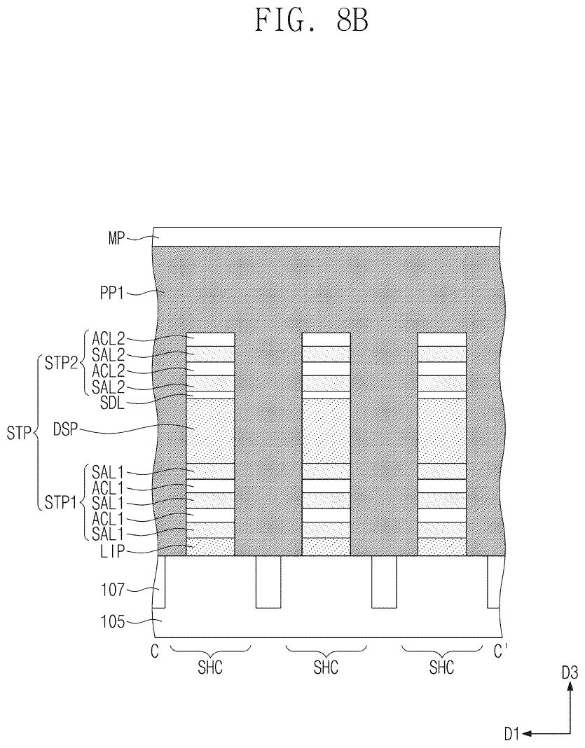

Referring to FIGS. 8A and 8B, an etching process may be performed on the stacked pattern STP using the gate spacers GS and the hard mask pattern MP as an etch mask. Through the etching process, a recess RS may be formed between adjacent first sacrificial patterns PP1. The stacked pattern STP may be formed in a shape of a vertical bar by the recess RS.

Sacrificial contact patterns PLH may be formed in the semiconductor substrate 105 exposed through the recess RS. The sacrificial contact patterns PLH may be formed in a contact shape. The sacrificial contact patterns PLH may be arranged in the second direction D2. The sacrificial contact patterns PLH may include a material that has etch selectivity to the semiconductor substrate 105, for example, silicon-germanium (SiGe). The sacrificial contact patterns PLH may be formed using an epitaxial growth process. The recess RS may expose the sacrificial contact pattern PLH. That is, the recess RS may overlap with the sacrificial contact pattern PLH.

In various example embodiments of the inventive concepts, when the separation layer DSL includes silicon germanium (SiGe), the separation layer DSL may be replaced with a silicon-based insulating material to form a dummy channel pattern DSP. The separation layer DSL exposed by the recess RS may be selectively removed, and a region from which the separation layer DSL has been removed may be filled with a silicon-based insulating material (e.g., silicon nitride).

A second lower insulating layer LIL2 may be formed on the sacrificial contact pattern PLH in the recess RS. An upper surface of the second lower insulating layer LIL2 may be coplanar with an upper surface of the lower insulating pattern LIP. The second lower insulating layer LIL2 may be formed of a silicon-based insulating material (e.g., silicon oxide, silicon oxynitride, or silicon nitride). However, example embodiments are not limited thereto. In various example embodiments, the second lower insulating layer LIL2 may be formed of the same material as the device isolation layer 107.

A lower source drain pattern LSD may be formed on the second lower insulating layer LIL2 in the recess RS. The lower source drain pattern LSD may be formed on the second lower insulating layer LI2. In detail, a first SEG process may be performed using a sidewall exposed by the recess RS of the lower stacked pattern STP1 as a seed layer to form the lower source drain pattern LSD. The lower source drain pattern LSD may be grown using the first active layers ACL1 exposed by the recess RS as a seed. As an example, the first SEG process may include a chemical vapor deposition (CVD) process or a molecular beam epitaxy (MBE) process.

During the first SEG process, impurities may be injected in-situ into the lower source/drain pattern LSD. As another example, after the lower source/drain pattern LSD is formed, impurities may be injected into the lower source/drain pattern LSD. The lower source/drain pattern LSD may be doped to have a first conductivity type (e.g., N-type).

The first active layers ACL1 interposed between a pair of lower source/drain patterns LSD may form the lower channel pattern LCH. That is, the first and second semiconductor patterns SP1 and SP2 of the lower channel pattern LCH may be formed from the first active layers ACL1. The lower channel patterns LCH and lower source/drain patterns LSD may form a lower active region LAR, which is a bottom tier of a three-dimensional device.

The lower source drain pattern LSD may be formed to completely fill the space between the pair of lower channel patterns LCH. That is, the first SEG process may be performed for a sufficient time so that the lower source drain pattern LSD fills a space between the pair of lower channel patterns LCH to connect the pair of lower channel patterns LCH to each other.

A first interlayer insulating layer 110 may be formed to cover the lower source drain pattern LSD. As an example, before forming the first interlayer insulating layer 110, an insulating layer that conformally covers the lower source drain pattern LSD may be further formed.

In the recess RS, the first interlayer insulating layer 110 may cover a sidewall of the upper stacked pattern STP2. Thereafter, an upper portion of the first interlayer insulating layer 110 may be removed to expose the sidewall of the upper stacked pattern STP2 in the recess RS again. An upper source drain pattern USD may be formed on the exposed sidewall of the upper stacked pattern STP2. In detail, a second SEG process may be performed using the sidewall exposed by the recess RS of the upper stacked pattern STP2 as a seed layer to form the upper source drain pattern USD. The upper source drain pattern USD may be grown using the second active layers ACL2 exposed by the recess RS as a seed. The upper source drain pattern USD may be doped to have a second conductivity type (e.g., P type) different from the first conductivity type.

The second active layers ACL2 interposed between a pair of upper source and drain patterns USD may form an upper channel pattern UCH. That is, the third and fourth semiconductor patterns SP3 and SP4 of the upper channel pattern UCH may be formed from the second active layers ACL2. The upper channel patterns UCH and upper source drain patterns USD may form an upper active region UAR, which is a top tier of the three-dimensional device. The second SEG process may also be performed for a sufficient time so that the upper source drain pattern USD completely fills a space between the pair of upper channel patterns UCH.

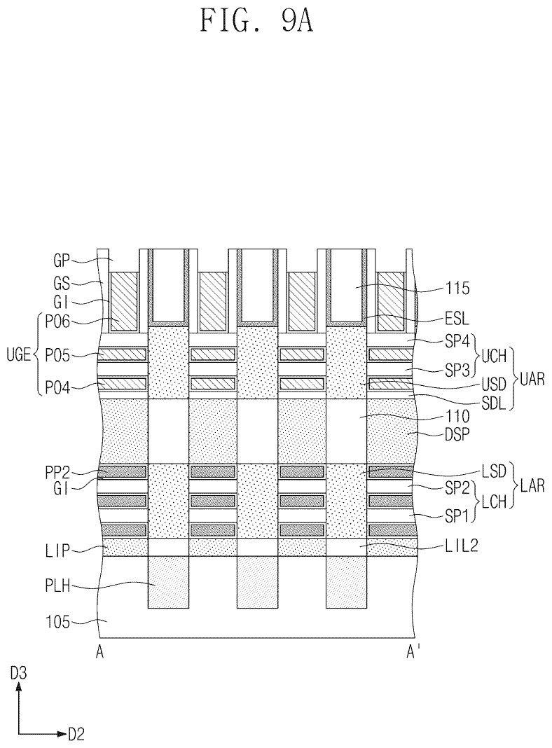

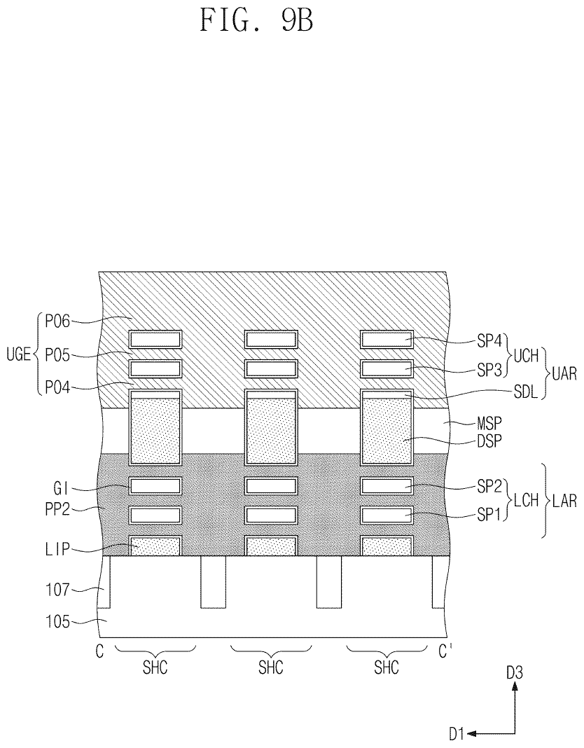

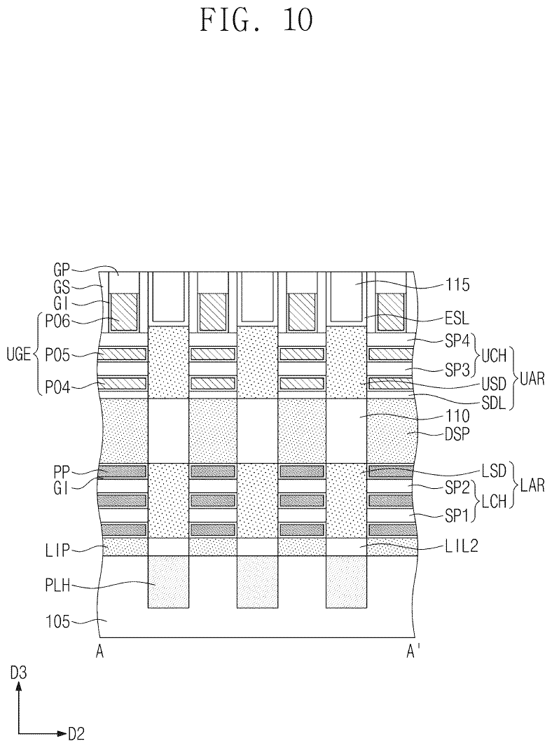

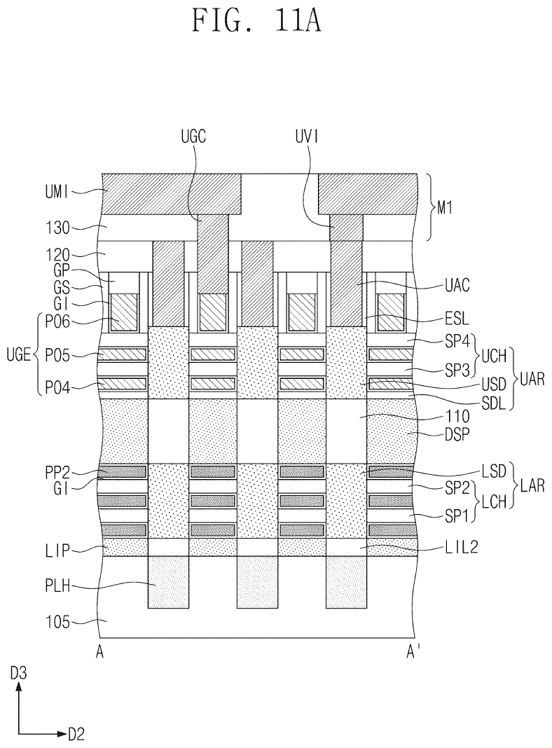

Referring to FIGS. 9A and 9B, a first preliminary insulating layer ESL may be conformally formed on the upper source/drain pattern USD. A buried insulating layer 115 filling the recess RS may be formed on the first preliminary insulating layer ESL. As an example, the buried insulating layer 115 may include a silicon oxide layer.

The buried insulating layer 115 may be planarized so that an upper surface of the first sacrificial pattern PPI of FIGS. 8A and 8B is exposed. Planarizing the buried insulating layer 115 may be performed using an etch back or chemical mechanical polishing (CMP) process. During the planarization process, all hard mask patterns MP on the first sacrificial pattern PPI may be removed. As a result, an upper surface of the buried insulating layer 115 may be coplanar with an upper surface of the first sacrificial pattern PP1 and upper surfaces of the gate spacers GS.

The exposed first sacrificial pattern PPI may be selectively removed. Removing the first sacrificial pattern PPI may include wet etching using an etchant that selectively etch polysilicon. The first sacrificial pattern PP1 may be removed to expose the first and second sacrificial layers SAL1 and SAL2.

An etching process may be performed to selectively etch the first and second sacrificial layers SAL1 and SAL2 to remove the first and second sacrificial layers SAL1 and SAL2 while first to fourth semiconductor patterns SP1 to SP4 and the dummy channel pattern DSP are left intact. The etching process may have a high etch rate for silicon germanium. For example, the etching process may have a high etch rate for silicon germanium with a germanium concentration greater than 10 at %.

A gate insulating layer GI may be conformally formed in a region where the first sacrificial pattern PP1 and the first and second sacrificial layers SAL1 and SAL2 have been removed. After the gate insulating layer GI is formed, a second sacrificial pattern PP2 may be formed in the lower active region LAR. A second sacrificial pattern PP2 may be formed on the substrate 105 and the device isolation layer 107. The second sacrificial pattern PP2 may not be formed on the upper active region UAR. The second sacrificial pattern PP2 may surround upper surface, bottom surface, and both sidewalls of each of the lower channel patterns LCH. The second sacrificial pattern PP2 may be formed on at least a portion of bottom and side surfaces of the dummy channel pattern DSP. The second sacrificial pattern PP2 may include amorphous silicon and/or polysilicon. The second sacrificial pattern PP2 may include the same material as the first sacrificial pattern PP1.

A separation pattern MSP may be formed on the second sacrificial pattern PP2. The separation pattern MSP may surround at least a portion of side surface of the dummy channel pattern DSP. A thickness of the separation pattern MSP may be smaller than a thickness of the dummy channel pattern DSP. An upper surface of the separation pattern MSP may be positioned at a lower level than an upper surface of the dummy channel pattern DSP. The separation pattern MSP may be interposed between the upper active region UAR and the lower active region LAR. Accordingly, the upper active region UAR and lower active region LAR may be distinguished by the separation pattern MSP.

An upper gate electrode UGE may be formed on the gate insulating layer GI of the upper active region UAR. The upper gate electrode UGE may be formed on a middle insulating layer MSP. Forming the upper gate electrode UGE may include forming fourth and fifth inner electrodes PO4 and PO5 between the third and fourth semiconductor patterns SP3 and SP4, and forming an outer electrode PO6 on the fourth semiconductor pattern SP4.

Referring to FIG. 10, the upper gate electrode UGE may be recessed and a height thereof may be reduced. A gate capping pattern GP may be formed on the recessed upper gate electrode UGE. A planarization process may be performed on the gate capping pattern GP so that an upper surface of the gate capping pattern GP is coplanar with an upper surface of the buried insulating layer 115.

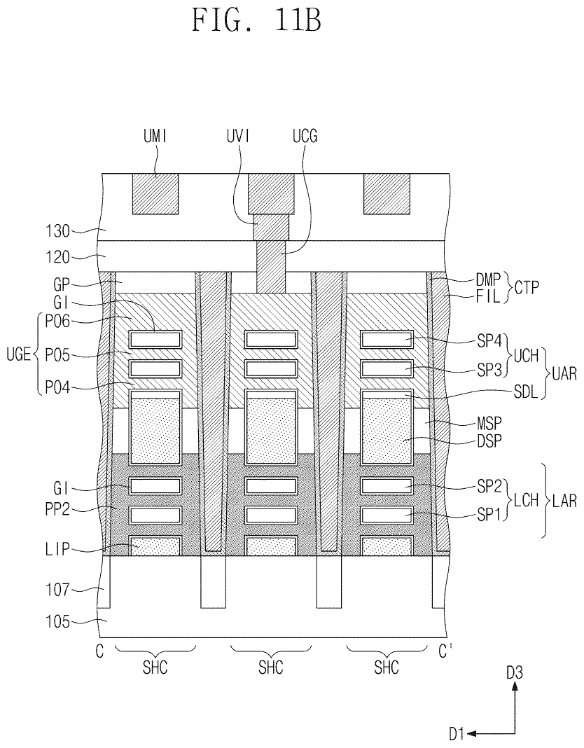

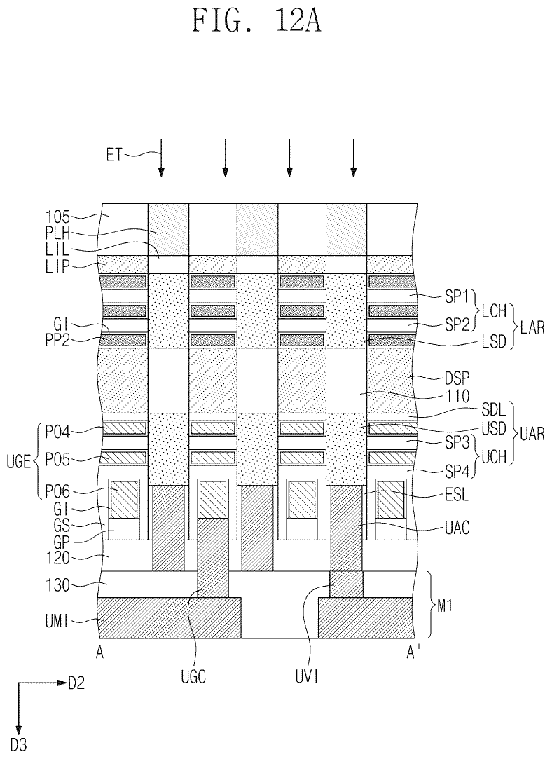

Referring to FIGS. 11A and 11B, a cutting pattern CTP may be formed penetrating the gate capping pattern GP, the upper gate electrode UGE, the separation pattern MSP, and the second sacrificial pattern PP2. Forming the cutting pattern CTP may include forming a through via penetrating the upper gate electrode UGE, the separation pattern MSP, and the second sacrificial pattern PP2, conformally forming a liner layer DMP in the through via, and forming a buried metal via FIL on the liner layer DMP. For example, the buried metal via FIL may be formed of a metal selected from the group consisting of copper (Cu), aluminum (Al), ruthenium (Ru), cobalt (Co), tungsten (W), and molybdenum (Mo). However, example embodiments are not limited thereto.

Upper active contacts UAC may be formed through the second interlayer insulating layer 120 and connected to the upper source/drain patterns USD, respectively. An upper gate contact UGC may be formed through the second interlayer insulating layer 120 and the gate capping pattern GP and connected to the gate electrodes GE. For example, the upper active contact UAC and upper gate contact UGC may be formed of a metal selected from the group consisting of copper (Cu), aluminum (Al), ruthenium (Ru), cobalt (Co), tungsten (W), and molybdenum (Mo). However, example embodiments are not limited thereto.

A third interlayer insulating layer 130 may be formed to cover the second interlayer insulating layer 120. A first metal layer M1 including upper interconnections UMI may be formed in the third interlayer insulating layer 130. Upper vias UVI may be formed to electrically connect the first metal layer M1 to the gate contacts GC and the upper active contacts UAC. A BEOL layer including additional metal layers (e.g., M2, M3, M4, etc.) may be formed on the first metal layer M1.

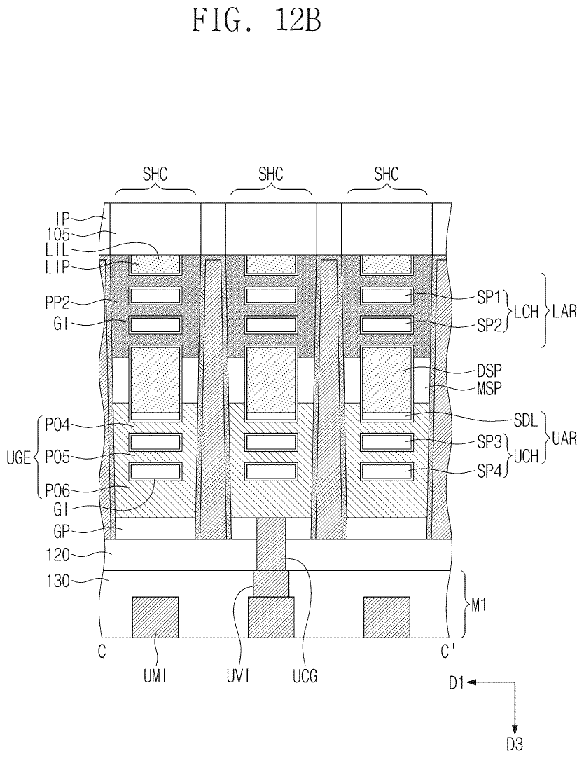

Referring to FIGS. 12A and 12B, the semiconductor substrate 105 may be turned over so that a back surface of the semiconductor substrate 105 is exposed. An etching process may be performed on the back surface of the semiconductor substrate 105, a height of the semiconductor substrate 105 may be reduced. A planarization process may be performed on the back surface of the semiconductor substrate 105 so that upper surfaces of the sacrificial contact patterns PLH are exposed.

The device isolation layer 107 may be removed, and a buried insulating pattern IP may be formed on the cutting pattern CTP. The buried insulating pattern IP may be formed of a silicon-based insulating material (e.g., silicon oxide, silicon oxynitride, or silicon nitride).

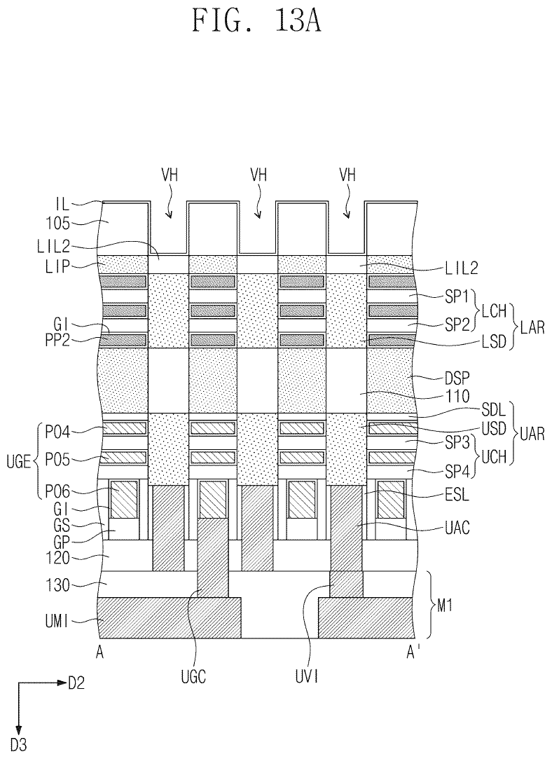

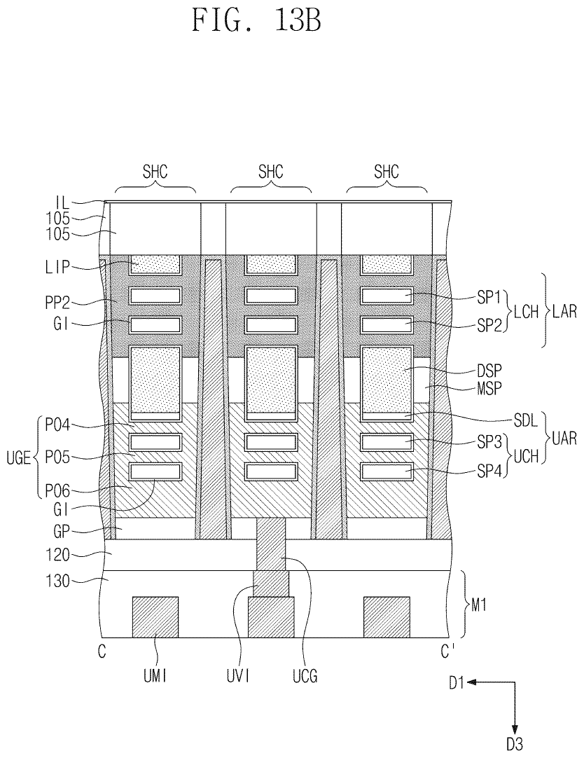

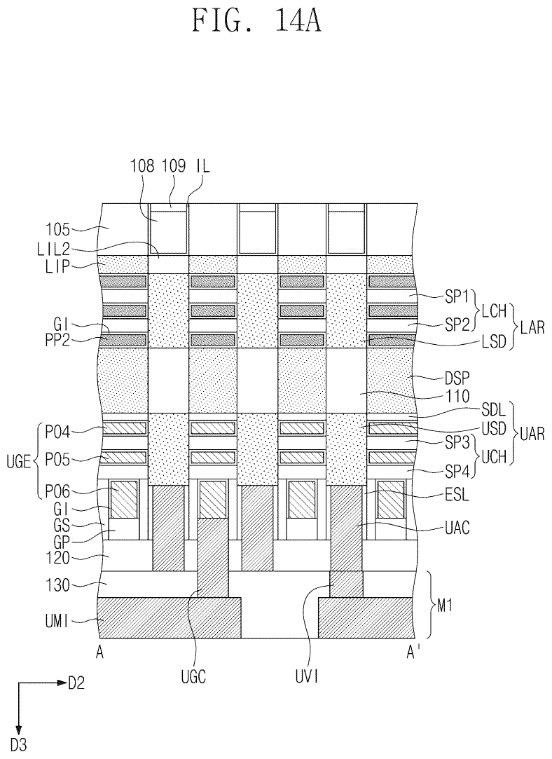

Referring to FIGS. 13A and 13B, exposed sacrificial contact patterns PLH may be selectively removed to form recess holes VH. The sacrificial contact patterns PLH may be removed to expose an upper surface of the second lower insulating layer LIL2. An insulating layer IL may be conformally formed on the semiconductor substrate 105, the exposed second lower insulating layer LIL2, and the buried insulating pattern IP.

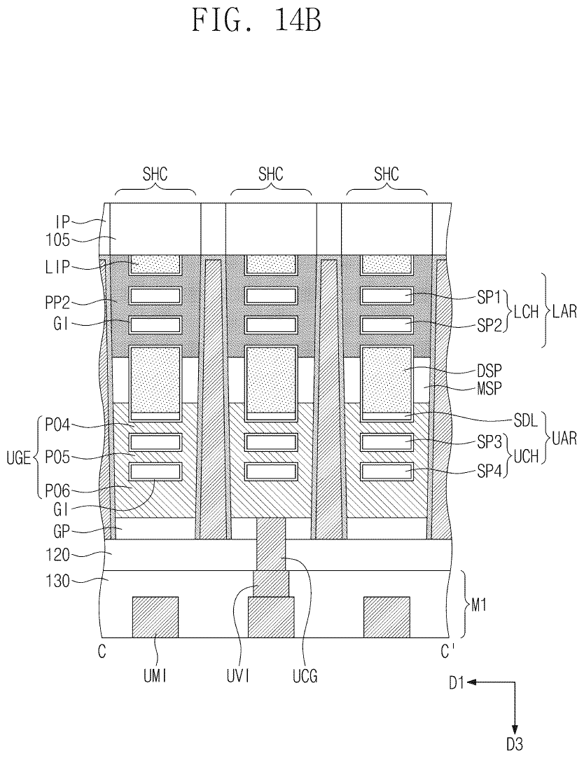

Referring to FIGS. 14A and 14B, a planarization process may be performed on the back surface of the semiconductor substrate 105 so that the insulating layer IL on the buried insulating pattern IP is removed. A second preliminary insulating layer 108 and a third preliminary insulating layer 109 may be formed on the insulating layer IL in the recess holes VH. The third preliminary insulating layer 109 may be formed on the second preliminary insulating layer 108. An upper surface of the second preliminary insulating layer 109 may be coplanar with an upper surface of the semiconductor substrate 105. The first preliminary insulating layer 108 and the second preliminary insulating layer 109 may be formed of an insulating material (e.g., silicon oxide, silicon oxynitride, or silicon nitride) of the silicon substrate. However, example embodiments are not limited thereto.

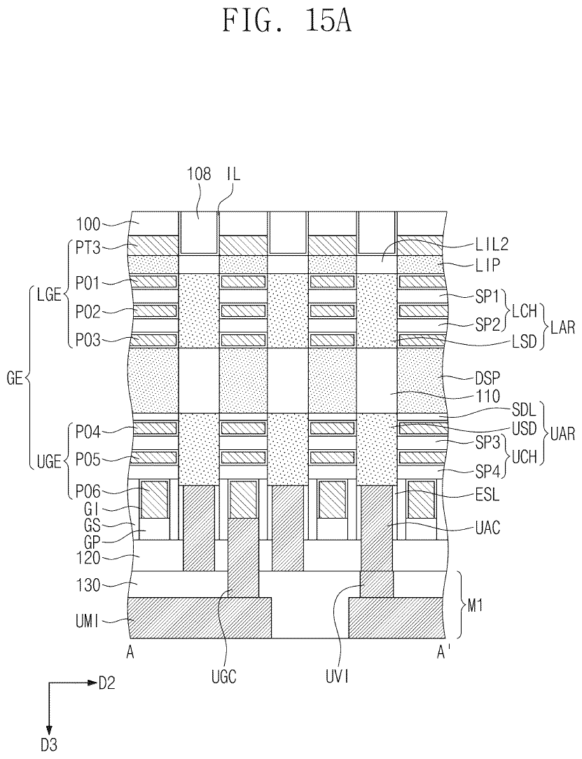

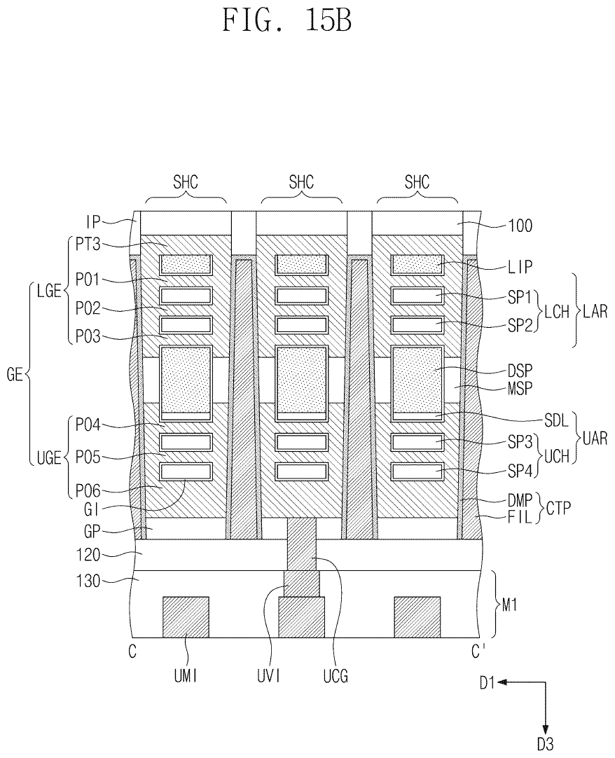

Referring to FIGS. 15A and 15B, the semiconductor substrate 105 may be selectively removed to expose the second sacrificial pattern PP2 and the lower insulating pattern LIP. The exposed second sacrificial pattern PP2 may be selectively removed. After the second sacrificial pattern PP2 is removed, a lower gate electrode LGE may be formed on the gate insulating layer GI of the lower active region LAR.

The lower gate electrode LGE may be formed on the separation pattern MSP. Forming the lower gate electrode LGE may include forming a first inner electrode PO1 between the first semiconductor pattern SP1 and the lower insulating pattern LIP, forming second inner electrodes PO2 between the first and second semiconductor patterns SP1 and SP2, forming a third inner electrode PO3 between the dummy channel pattern DSP and the second semiconductor pattern, and forming the third portion PT3 on the lower insulating pattern LIP.

An upper surface of the lower gate electrode LGE may be positioned at a higher level than an upper surface of the lower insulating pattern LIP. The lower gate electrode LGE may be formed to surround top, bottom, and both sidewalls of the lower insulating pattern LIP. An upper surface of the lower gate electrode LGE may be higher than an upper surface of the cutting pattern CTP. The lower gate electrode LGE may extend from the separation pattern MSP in the vertical direction D3.

A substrate 100 may be formed on the lower gate electrode LGE. An upper surface of the substrate 100 may be substantially coplanar with an upper surface of the buried insulating pattern IP. The substrate 100 may be formed of a silicon-based insulating material (e.g., silicon oxide, silicon oxynitride, or silicon nitride).

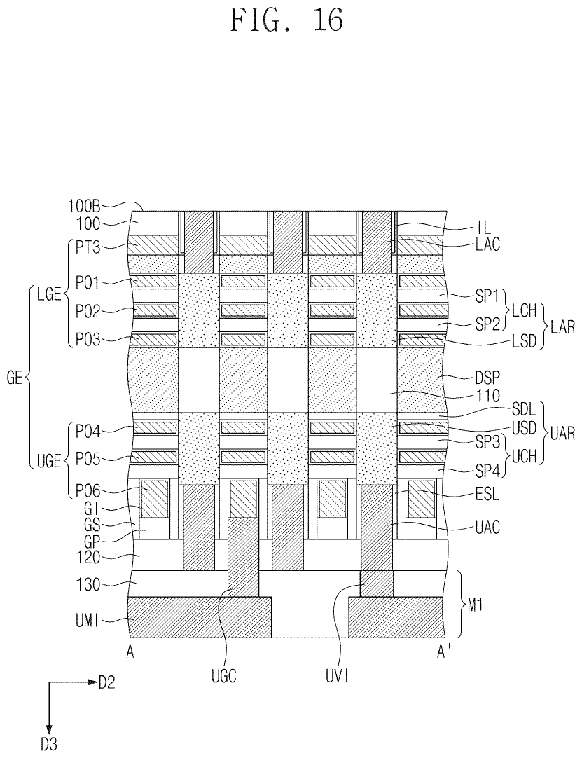

Referring to FIG. 16, an etching process may be performed on a second surface 100B of the substrate 100 to expose the lower source/drain pattern LSD. A lower active contact LAC connected to the exposed lower source drain pattern LSD may be formed. The lower active contact LAC may be formed in a self-aligned manner.

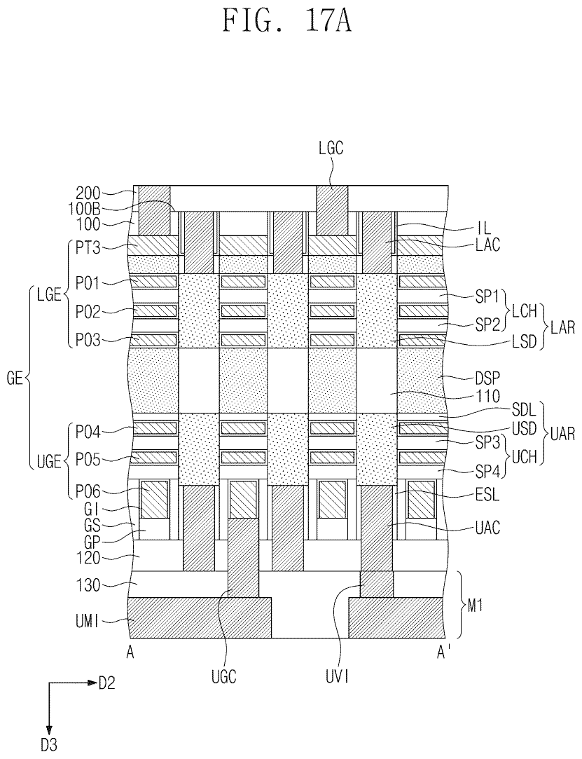

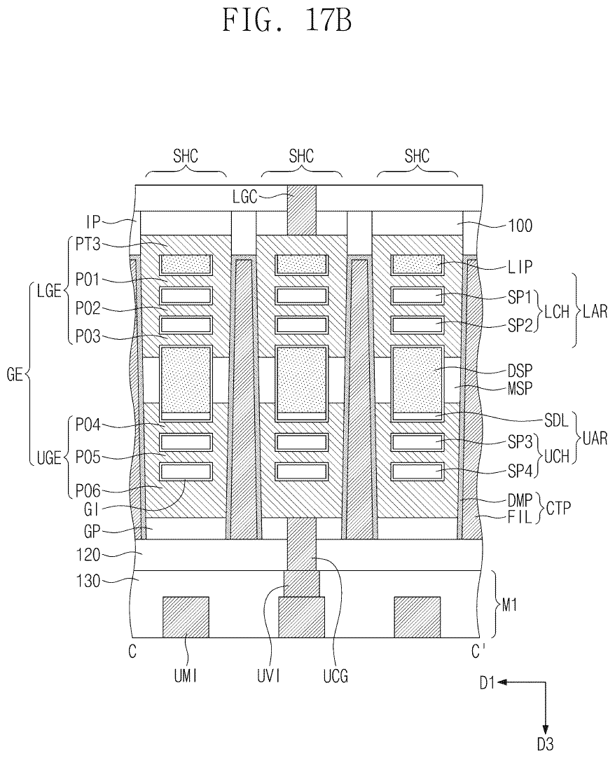

Referring to FIGS. 17A and 17B, a first lower interlayer insulating layer 200 may be formed on the second surface 100B of the substrate 100. A lower gate contact LGC may be formed through the substrate 100 and the first lower interlayer insulating layer 200 to be connected to the lower gate electrode LGE. The lower gate contact LGC may be electrically connected to the third portion PT3 of the lower gate electrode LGE.

Referring again to FIGS. 4A to 4C, a second lower interlayer insulating layer 210 may be formed on the first lower interlayer insulating layer 200. A backside metal layer BSM may be formed in the second lower interlayer insulating layer 210. The backside metal layer BSM may include lower interconnections LMI. Lower vias LVI may be formed to electrically connect the backside metal layer BSM to the lower active contact LAC and lower gate contact LGC. Additional backside metal layers may be formed on the backside metal layer BSM. In various example embodiments of the inventive concepts, the backside metal layers may include a power transmission network.

The three-dimensional semiconductor device according to the inventive concept may include the lower insulating pattern under the channel pattern, and may include the lower gate electrode under the lower insulating pattern. Accordingly, the lower gate contact connected to the lower gate electrode may have the height difference from the lower active contact. Accordingly, the occurrence of electrical shorts between the lower gate contact and the lower active contact may be prevented or reduced. As a result, the reliability and electrical characteristics of three-dimensional semiconductor devices may be improved.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A three-dimensional semiconductor device comprising:
a first active region on a substrate, including a lower channel pattern and a lower source/drain pattern connected to the lower channel pattern, the lower channel pattern including a plurality of lower semiconductor patterns stacked and spaced apart from each other in a first direction that is perpendicular to an upper surface of the substrate, and the lower semiconductor patterns including a first semiconductor pattern;
a second active region stacked on the first active region, including an upper channel pattern and an upper source/drain pattern connected to the upper channel pattern;
a lower gate electrode on the lower channel pattern; and
a lower insulating pattern under the first semiconductor pattern, the first semiconductor pattern spaced apart from the lower insulating pattern in the first direction,
wherein the lower gate electrode includes
a first portion adjacent to a first sidewall of the lower insulating pattern and extending in the first direction from an upper surface to a bottom surface of the lower gate electrode,
a second portion adjacent to a second sidewall of the lower insulating pattern and extending in the first direction from the upper surface to the bottom surface of the lower gate electrode, the second sidewall facing the first sidewall in a second direction which is perpendicular to the first direction, and
a third portion in contact with a bottom surface of the lower insulating pattern and extending from the first portion to the second portion in the second direction.

2. The three-dimensional semiconductor device of claim 1, wherein a width of the lower gate electrode in the second direction decreases from the bottom surface of the lower gate electrode to the bottom surface of the lower insulating pattern.

3. The three-dimensional semiconductor device of claim 1, wherein an inner electrode of the lower gate electrode is interposed between the first semiconductor pattern and the lower insulating pattern.

4. The three-dimensional semiconductor device of claim 1, further comprising an upper gate electrode on the upper channel pattern,
wherein the upper gate electrode and the lower gate electrode are spaced apart from each other in the first direction with a separation pattern therebetween.

5. The three-dimensional semiconductor device of claim 1, wherein a width of each of the first portion and the second portion increases as the first portion and the second portion approach the bottom surface of the lower insulating pattern.

6. The three-dimensional semiconductor device of claim 1, further comprising a lower gate contact electrically connected to the third portion.

7. The three-dimensional semiconductor device of claim 6, further comprising a lower active contact electrically connected to the lower source/drain pattern,
wherein an upper surface of the lower active contact is positioned at a higher level than an upper surface of the lower gate contact.

8. The three-dimensional semiconductor device of claim 1, further comprising a gate insulating layer between the upper surface and both sidewalls of the lower insulating pattern and the lower gate electrode.

9. The three-dimensional semiconductor device of claim 1, wherein a maximum width of the lower gate electrode is greater than a maximum width of the lower insulating pattern.

10. The three-dimensional semiconductor device of claim 1, wherein the lower source/drain pattern has a first conductivity type, and
the upper source/drain pattern has a second conductivity type different from the first conductivity type.

11. A three-dimensional semiconductor device comprising:
a first active region on a substrate, including a lower channel pattern and a lower source/drain pattern connected to the lower channel pattern, the lower channel pattern including a plurality of lower semiconductor patterns stacked and spaced apart from each other in a first direction, and the lower semiconductor patterns including a first semiconductor pattern;
a second active region stacked on the first active region, including an upper channel pattern and an upper source/drain pattern connected to the upper channel pattern;
a lower gate electrode on the lower channel pattern; and
a lower insulating pattern under the first semiconductor pattern,
wherein the first semiconductor pattern is spaced apart from the lower insulating pattern in the first direction, and
wherein the lower gate electrode surrounds upper surface, both sidewalls, and bottom surface of the lower insulating pattern.

12. The three-dimensional semiconductor device of claim 11, wherein an inner electrode of the lower gate electrode is interposed between the first semiconductor pattern and the lower insulating pattern.

13. The three-dimensional semiconductor device of claim 11, further comprising an upper gate electrode on the upper channel pattern,
wherein the upper gate electrode and the lower gate electrode are spaced apart from each other in the first direction with a separation pattern therebetween.

14. The three-dimensional semiconductor device of claim 11, wherein a width of the lower gate electrode increases as the lower gate electrode approaches the bottom surface of the lower insulating pattern.

15. The three-dimensional semiconductor device of claim 11, further comprising a lower gate contact electrically connected to the lower gate electrode.

16. A three-dimensional semiconductor device comprising:
a first active region on a substrate, including a lower channel pattern and a lower source/drain pattern connected to the lower channel pattern, the lower channel pattern including a plurality of lower semiconductor patterns stacked and spaced apart from each other in a first direction, and the lower semiconductor patterns including a first semiconductor pattern;
a second active region stacked on the first active region, including an upper channel pattern and an upper source/drain pattern connected to the upper channel pattern;
a lower gate electrode on the lower channel pattern;
a lower gate contact electrically connected to the lower gate electrode; and
a lower insulating pattern under the first semiconductor pattern,
wherein the first semiconductor pattern is spaced apart from the lower insulating pattern in the first direction,
wherein a level of a bottom surface of the lower gate electrode is lower than a level of a bottom surface of the lower insulating pattern, and
wherein a maximum width of the lower gate electrode is greater than a maximum width of the lower insulating pattern.

17. The three-dimensional semiconductor device of claim 16, wherein the lower gate electrode surrounds an upper surface, both sidewalls, and the bottom surface of the lower insulating pattern.

18. The three-dimensional semiconductor device of claim 16, further comprising an upper gate electrode on the upper channel pattern,
wherein the upper gate electrode and the lower gate electrode are spaced apart from each other in the first direction with a separation pattern therebetween.

19. The three-dimensional semiconductor device of claim 16, further comprising a gate insulating layer between upper surface and both sidewalls of the lower insulating pattern and the lower gate electrode.

20. The three-dimensional semiconductor device of claim 16, wherein a width of the lower gate electrode in a second direction decreases from the bottom surface of the lower gate electrode to the bottom surface of the lower insulating pattern, the second direction being perpendicular to the first direction.
